(19) United States
(12) Patent Application Publication
(10) Pub. No.: US 2011/0215365 A1
(43) Pub. Date: Sep. 8, 2011

(54) SEMICONDUCTOR PACKAGE AND FABRICATION METHOD THEREOF

(75) Inventor: SHEN-BO LIN, Hukou (TW)

(73) Assignee: ADVANCED OPTOELECTRONIC TECHNOLOGY, INC., Hsinchu Hsien (TW)

(21) Appl. No.: 12/909,797

(22) Filed: Oct. 21, 2010

(30) Foreign Application Priority Data
Mar. 4, 2010 (CN) 201010117886.X

(51) Int. Cl. H01L 33/48; H01L 33/52

(52) U.S. Cl. 257/99; 438/28; 257/E33.059; 257/E33.056

(57) ABSTRACT

A light emitting element package includes a package substrate, at least one light emitting element, a first encapsulation layer and a second encapsulation layer. The at least one light emitting element is mounted on the package substrate. The first encapsulation layer is mounted on the package substrate for encapsulation the at least one light emitting element. The second encapsulation layer is configured for encapsulation a back side of the at least one light emitting element.

### BACKGROUND

1. Technical Field

The disclosure relates generally to semiconductor packages, and more particularly to a light emitting element package and fabrication method for the package.

2. Description of the Related Art

Often thicknesses of metal electrodes mounted on LED chips are not uniform. When the LED chips are bonded to a substrate, poor solder joins are often formed between the metal electrodes and the substrate.

Therefore, what is needed is a LED package that can alleviate the limitations described.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout two views.

FIGS. 1-10 are schematic views of a fabrication method for a light emitting element package in accordance with one embodiment of the disclosure.

FIG. 11 is a cross-section of a light emitting element package in accordance with one embodiment of the disclosure.

### DETAILED DESCRIPTION

The disclosure is illustrated by way of example and not by way of limitation in the figures of the accompanying drawings. It should be noted that references to “an” or “one” embodiment in this disclosure are not necessarily to the same embodiment, and such references mean at least one.

A method for light emitting element package is as follows.

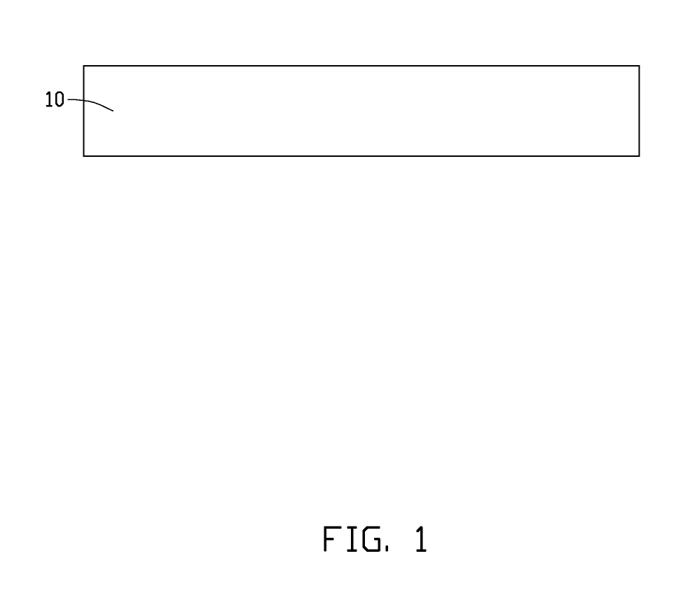

Referring to FIG. 1, a temporary substrate 10 is provided. The temporary substrate 10 can be Al₂O₃, SiC, LiAlO₂, LiGaO₂, Si, GaN, ZnO, AlZnO, GaAs, GaP, GaSb, InP, InAs or ZnSe.

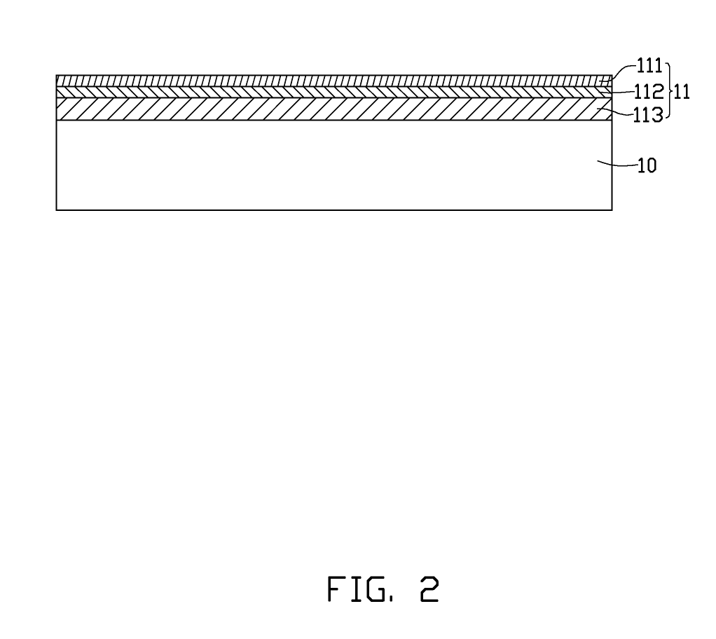

Referring to FIG. 2, a semiconductor unit 11 is formed on the temporary substrate 10. The semiconductor unit 11 can be formed by chemical vapor deposition (CVD), metal organic chemical vapor deposition (MOCVD) or molecular beam epitaxy (MBE). The semiconductor unit 11 can be group III-V elements or group II-VI elements. In the embodiment, the semiconductor unit 11 includes a p-type semiconductive layer 111, a light emitting layer 112 and an n-type semiconductive layer 113. The light emitting layer 112 is single layer hetero structure, double heterostructure, single quantum well or multiple quantum well structure.

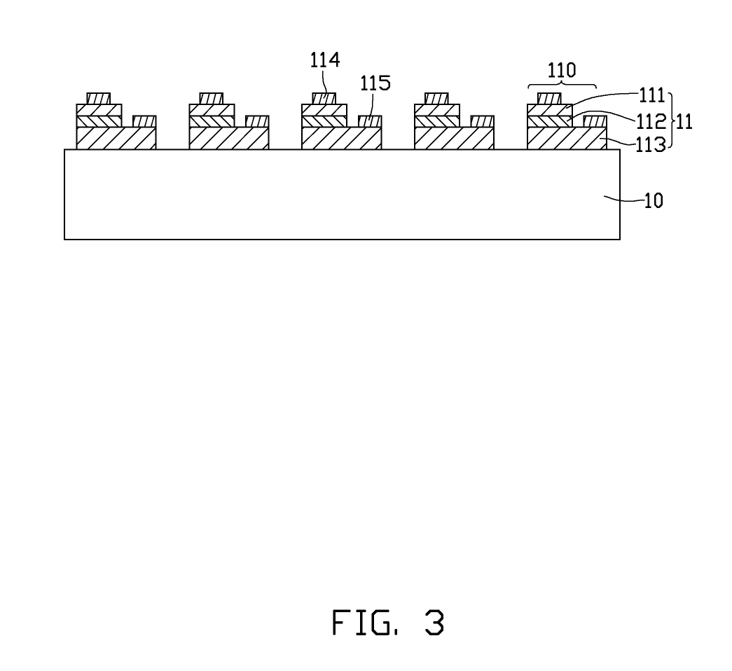

Referring to FIG. 3, a plurality of light emitting elements 110 is formed on the semiconductor unit 11 by photolithography or lithography. Each of the light emitting elements 110 further includes a first electrode 114 and a second electrode 115. Each first electrode 114 is electrically coupled to the p-type semiconductive layer 111. Each second electrode 115 is electrically coupled to the n-type semiconductive layer 113. The first electrodes 114 and the second electrodes 115 are Ni, Cr, Au, Ag, Pt, Cu, Zn, Ti, Si or a combination thereof. The first electrodes 114 and the second electrodes 115 are formed by evaporation, sputtering or etching.

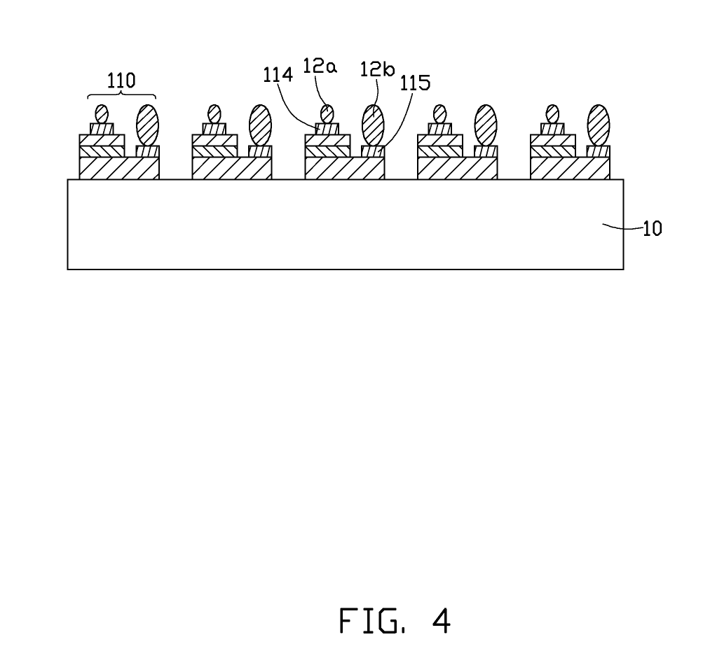

Referring to FIG. 4, a plurality of first protrusions 12a is formed on the first electrodes 114. A plurality of second protrusions 12b is formed on the second electrodes 115. The first protrusions 12a and the second protrusions 12b are Ni, Sn, Cr, Cu, Au, Ag, Pb, Pt, Zn, Ti, Si or a combination thereof. The first protrusions 12a and the second protrusions 12b are formed by stencil printing.

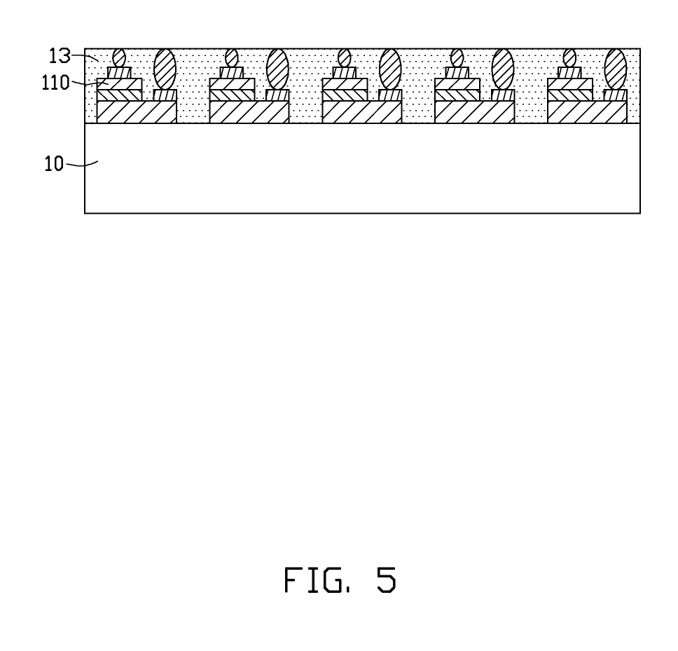

Referring to FIG. 5, a first encapsulation layer 13 is formed on the temporary substrate 10 to encapsulate the light emitting elements 110. The first encapsulation layer 13 is epoxy, silicone or a combination thereof. The first encapsulation layer 13 is formed by transfer molding, spin coating, or injection molding.

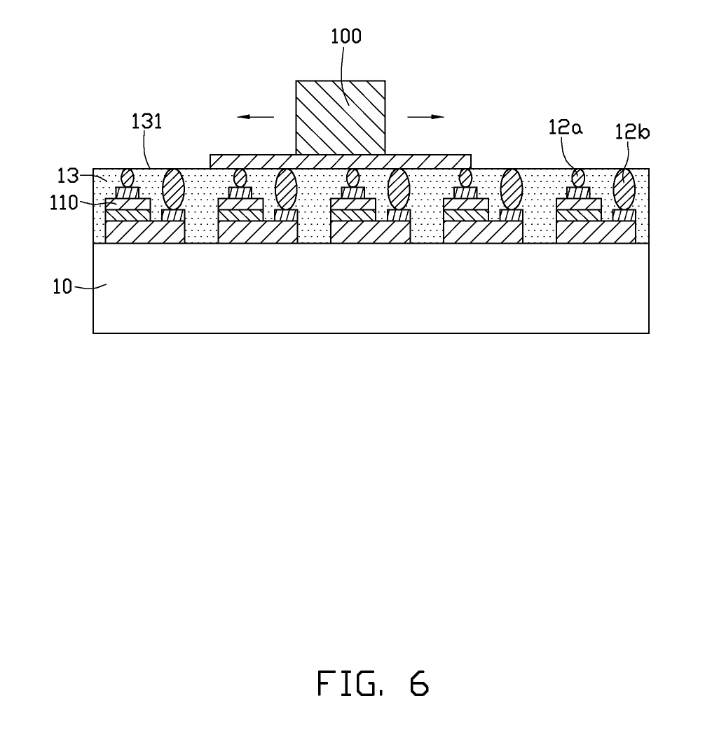

Referring to FIG. 6, a smooth surface 131 of the encapsulation layer 13 is obtained by grinding using grinding equipment 100. The first protrusions 12a and the second protrusions 12b can protrude from the surface 131.

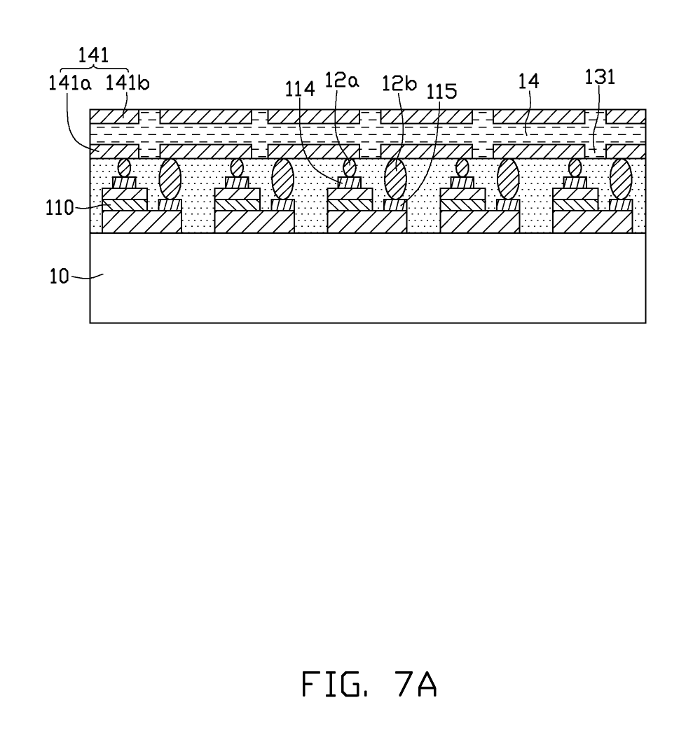

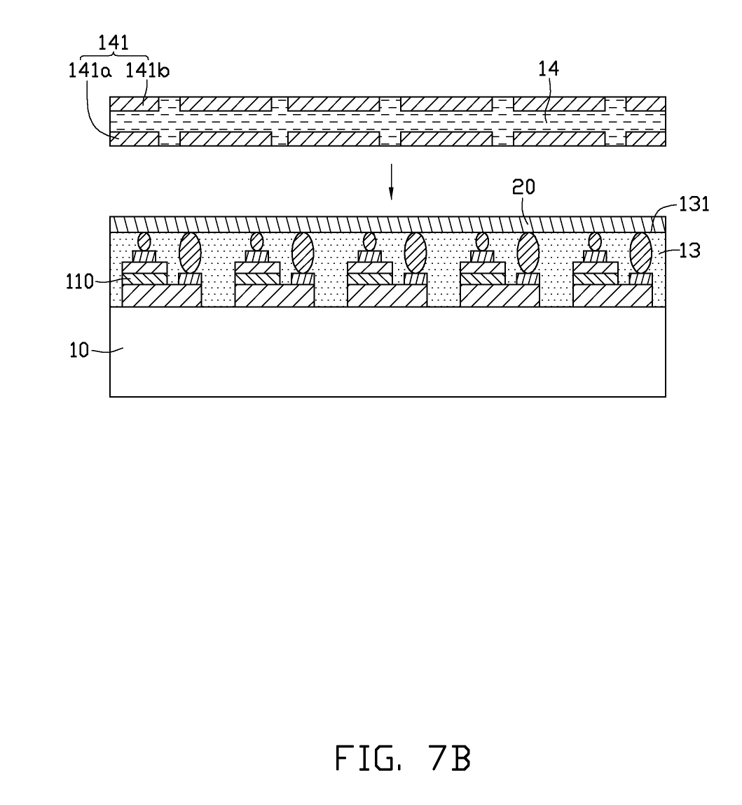

Referring to FIG. 7A, a package substrate 14 is mounted on the surface 131 of the first encapsulation layer 13. The package substrate 14 is a circuit module 141. The circuit module 141 is a plurality of first circuits 141a and a plurality of second circuits 141b. Each first circuit 141a is electrically connected to each second circuit 141b.

The first electrodes 114 and the second electrodes 115 are electrically coupled to the second circuits 141b through the first protrusions 12a, the second protrusions 12b and the first circuits 141a. The package substrate 14 can be plastic, polymer, ceramic, silicon, metal, or a combination thereof. The circuit module 141 is made of conductive materials, such as Cu, Ni, Au, Ag or a combination thereof.

Referring to FIG. 7B, the package substrate 14 is mounted on the surface 131 by an adhesive layer 20 of anisotropic conductive material. The adhesive layer 20 can be a film, a gel or a paste. The adhesive layer 20 is formed on the surface 131 by thermal transfer printing. The anisotropic conductive material is conductive in direction perpendicular to the surface 131 and nonconductive parallel thereto.

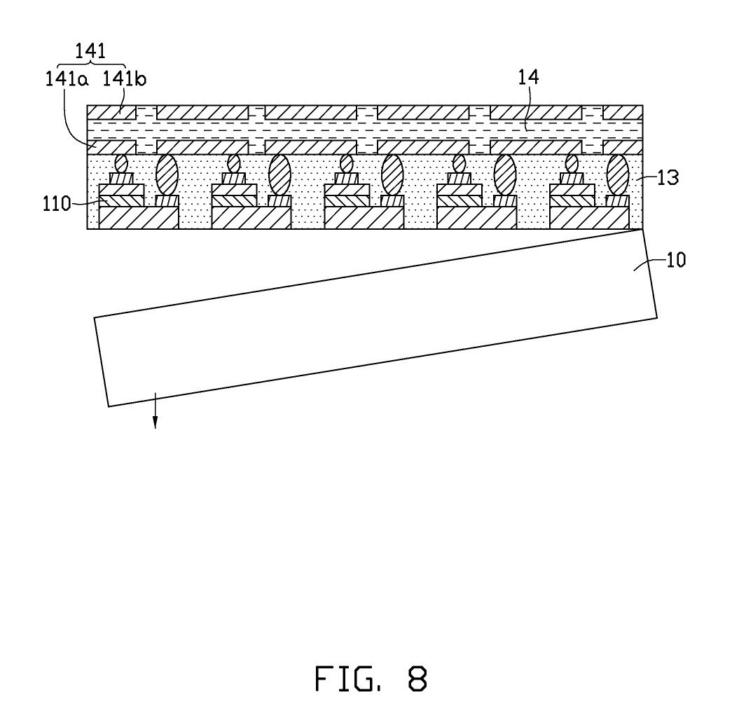

Referring to FIG. 8, the temporary substrate 10 is removed by lifting, etching, cutting, or grinding.

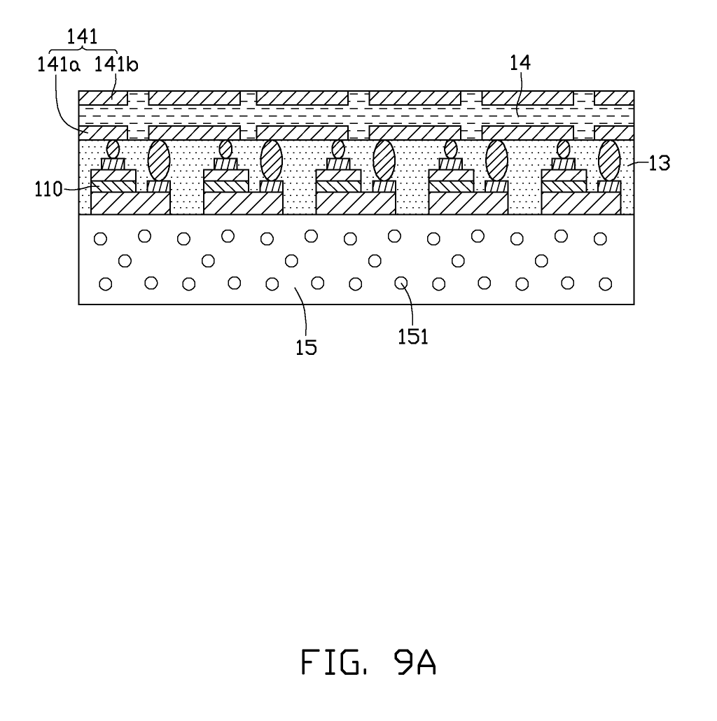

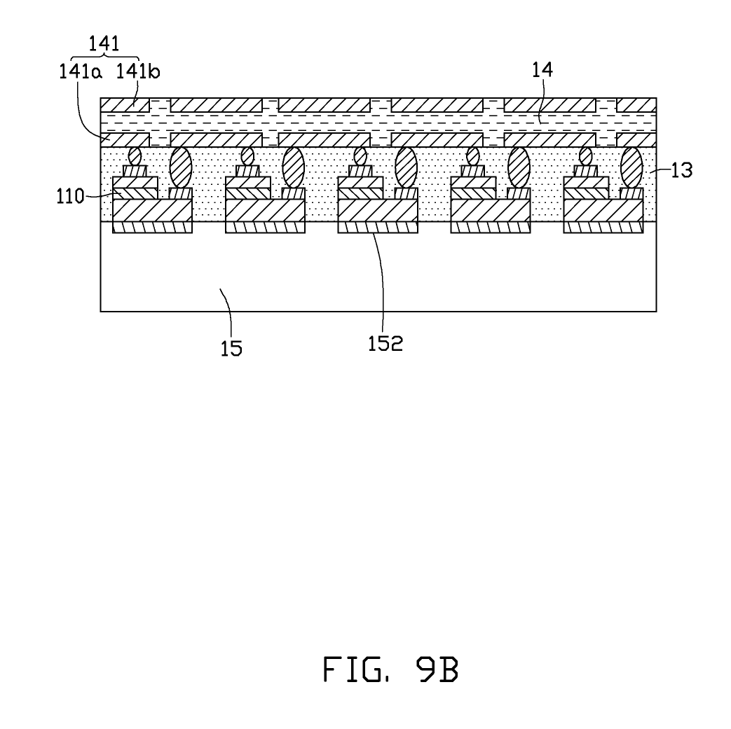

Referring to FIG. 9A, a second encapsulation layer 15 is formed on the downward surface of the light emitting elements 110. The second encapsulation layer 15 and the first encapsulation layer 13 are not coplanar. The second encapsulation layer 15 is opposite to the first encapsulation layer 13. The second encapsulation layer 15 is epoxy, silicone or a combination thereof.

The second encapsulation layer 15 further is a phosphor element 151. The phosphor element 151 is YAG, TAG, silicate, nitride, nitrogen oxide, phosphide, sulfide or a combination thereof.

The phosphor element 151 can be regularly distributed in the second encapsulation layer 14.

Referring to FIG. 9B, the phosphor element 152 is a patch. The phosphor element 151, 152 can also be a film or a lumiramic plate, not limited to the shape disclosed. The phosphor elements 151, 152 are formed by coating, paste, or spray.

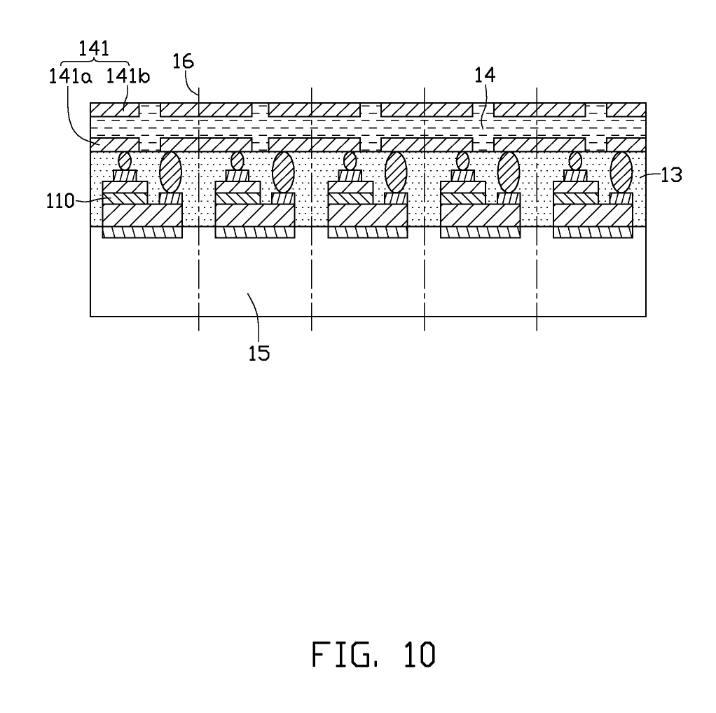

Referring to FIG. 10, a plurality of light emitting element packages 1 is diced by lifting. The semiconductor unit 11 is lifted along the scribe lines 16 to form the light emitting element packages 1.

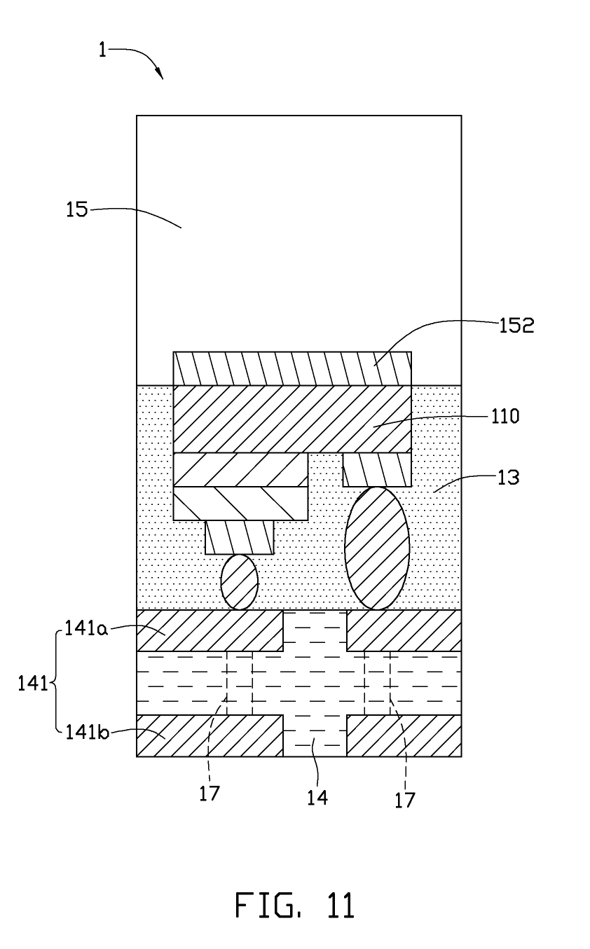

Referring to FIG. 11, each light emitting element package 1 is the circuit module 141 defined in the package substrate 14, light emitting element 110, first encapsulation layer 13, phosphor element 152 and the second encapsulation layer 15. The number of light emitting elements defined in one light emitting element package 1 can exceed two. The first circuit 141a is electrically coupled to the second circuit 141b through conductive traces 17 defined in the package substrate 14.

While the disclosure has been described by way of example and in terms of exemplary embodiment, it is to be understood that the disclosure is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A fabrication method for a light emitting element package, the method comprising:
providing a temporary substrate;
forming a semiconductor unit on the temporary substrate, the semiconductor unit comprising a plurality of light emitting elements, each comprising a first electrode and a second electrode;
forming a plurality of protrusions on the first electrodes and the second electrodes;
forming a first encapsulation layer on the temporary substrate to encapsulate the light emitting elements and the protrusions;
mounting a package substrate on the first encapsulation layer, the package substrate electrically coupled to the protrusions;
removing the temporary substrate;
forming a second encapsulation layer on a downward surface of the light emitting elements and the first encapsulation layer to obtain a semi-finished product, the first encapsulation layer and the second encapsulation layer not being coplanar; and
dicing the semi-finished product to form a plurality of light emitting element packages each corresponding to one of the light emitting elements.

2. The fabrication method for a light emitting element package of claim 1, wherein each light emitting element comprises a p-type semiconductive layer, a light emitting layer and an n-type semiconductive layer.

3. The fabrication method for a light emitting element package of claim 1, wherein the first encapsulation layer and the second encapsulation layer are formed by transfer molding, spin coating or injection molding, wherein the first encapsulation layer and second encapsulation layer comprise epoxy, silicone or a combination thereof.

4. The fabrication method for a light emitting element package of claim 1, further comprising:
obtaining a smooth surface of the first encapsulation layer by a grinding process.

5. The fabrication method for a light emitting element package of claim 1, wherein the package substrate is mounted on the first encapsulation layer by anisotropic conductive material.

6. The fabrication method for a light emitting element package of claim 5, wherein the anisotropic conductive material is formed by thermal transfer printing.

7. The fabrication method for a light emitting element package of claim 1, wherein the package substrate comprises a circuit module, the circuit module comprising a plurality of first circuits and a plurality of second circuits, the light emitting elements electrically coupled to the first circuits of the circuit module through the first protrusions and the second protrusions.

8. The fabrication method for a light emitting element package of claim 7, wherein the circuit module comprises a plurality of conductive traces, each first circuit electrically coupled to each second circuit through the conductive traces.

9. The fabrication method for a light emitting element package of claim 1, further comprising mounting at least one phosphor layer on the light emitting elements.

10. The fabrication method for a light emitting element package of claim 9, wherein the at least one phosphor layer comprises YAG, TAG, silicate, nitride, nitrogen oxide, phosphide, sulfide or a combination thereof.

11. A light emitting element package comprising:
a package substrate;
at least one light emitting element mounted on the package substrate;
a first encapsulation layer mounted on the package substrate for encapsulation the at least one light emitting element; and
a second encapsulation layer configured for encapsulation a back side of the at least one light emitting element.

12. The light emitting element package of claim 11, wherein the package substrate comprises a circuit module, the circuit module electrically connected to the at least one light emitting element.
